(19) United States
(12) Patent Application Publication
(10) Pub. No.: US 2009/0201255 A1
(43) Pub. Date: Aug. 13, 2009

(54) Input device and operating method thereof

(75) Inventor: Meng-Ju Lee, Taipei Hsien (TW)

Correspondence Address: REED SMITH LLP;Suite 1400, 3110 Fairview Park Drive, Falls Church, VA, 22042, US

(73) Assignee: Compal Communications, Inc.

(21) Appl. No.: 12/292,667

(22) Filed: Nov. 24, 2008

(30) Foreign Application Priority Data
Nov. 23, 2007 (TW) 096144400

(51) Int. Cl. G06F 3/02; H03K 17/94

(52) U.S. Cl. 345/168; 341/22

(57) ABSTRACT

The invention provides an input device. The input device comprises a plurality of keys, a recording module, a database, an analyzing module, and a selecting module. The recording module is connected to the keys, for recording a former keystroke sequence and voltage variation information related to the keys. The database is for storing a plurality set of default data. The analyzing module is connected to the recording module and the database, for generating a set of pressed probabilities related to the keys based on the plurality set of default data and the former keystroke sequence. The selecting module is connected to the recording module and the analyzing module, for selecting a target key from the plurality of keys based on the set of pressed probabilities and the voltage variation information.

### BACKGROUND OF THE INVENTION

1. Field of the Invention

The present invention relates generally to an input device, and more particularly, the present invention relates to an input device which can judge a pressed key and an operating method thereof.

2. Description of the Prior Art

With the development of technology recently, each kind of various input devices has become smaller, thinner and lighter, as well as the keys of input devices. Therefore, users usually carelessly press several keys at the same time while inputting.

Take mobile phones for example, presently general mobile phones mostly adopt capacitance keys, which judges users' destination of pressed key by means of regarding the key which has a maximum voltage variation (caused by the capacitance variation) as the users' destination of pressed key, and the others pressed at the same time are regarded as static keys. However, when a plurality of keys are pressed simultaneously so that the capacitance variation (or voltage variation) of each key is very similar, the way of judging often results in an erroneous judgment.

Accordingly, the main aspect of the present invention is to provide an input device which can judge a pressed key and an operating method thereof to solve the problems mentioned above.

### SUMMARY OF THE INVENTION

Accordingly, the invention provides an input device which can judge a pressed key and an operating method thereof. When users using the input device carelessly press several keys at the same time, the input device and the operating method thereof not only records voltage variation information related to the keys but also precisely generates a set of pressed probabilities related to the keys by means of analyzing a former keystroke sequence and a database. Thereby, the users' destination of pressed key can be selected from the pressed keys based on the set of pressed probability

An input device of the present invention comprises a plurality of keys, a recording module, a database, an analyzing module, and a selecting module. The recording module is connected to the keys, for recording a former keystroke sequence and voltage variation information related to the keys. The database is for storing a plurality set of default data. The analyzing module is connected to the recording module and the database, for generating a set of pressed probabilities related to the keys based on the plurality set of default data and the former keystroke sequence. The selecting module is connected to the recording module and the analyzing module, for selecting a target key from the plurality of keys based on the set of pressed probabilities and the voltage variation information.

Compared to the prior art, the input device and the operating method thereof of the invention can reduce the probability of erroneous judgment while the plurality of capacitance keys are pressed simultaneously so that the voltage variation of each key is very similar.

The objective of the present invention will no doubt become obvious to those of ordinary skill in the art after reading the following detailed description of the preferred embodiment, which is illustrated in the various figures and drawings.

### BRIEF DESCRIPTION OF THE APPENDED DRAWINGS

FIG. 1 is a functional block illustrating an input device according to the first embodiment of the invention.

FIG. 2 is a flow chart demonstrating a method of operating the input device according to the second embodiment of the invention.

### DETAILED DESCRIPTION OF THE INVENTION

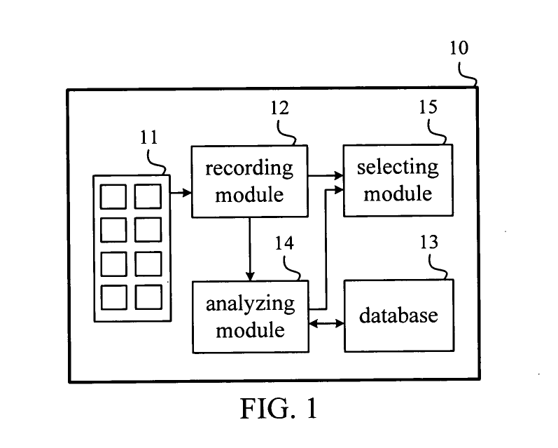

The first embodiment of the present invention is an input device. Please refer to FIG. 1, FIG. 1 is a functional block illustrating an input device of the first embodiment. As illustrated in FIG. 1, the input device 10 comprises a plurality of keys 11, a recording module 12, a database 13, an analyzing module 14, and a selecting module 15. The keys 11 could be capacitance keys, any kind of touch keys, film keys, any kind of mechanical keys or others.

The recording module 12 is connected to the keys 11, for recording a former keystroke sequence and voltage variation information related to the keys 11. The database 13 is for storing a plurality set of default data. The analyzing module 14 is connected to the recording module 12 and the database 13, for generating a set of pressed probabilities related to the keys 11 based on the plurality set of default data and the former keystroke sequence. The selecting module 15 is connected to the recording module 12 and the analyzing module 14, for selecting a target key from the plurality of keys 11 based on the set of pressed probabilities and the voltage variation information. Moreover, in a practical application, the analyzing module 14 can store the analyzed pressed probability in the recording module 12 so that the recording module 12 even comprises a stored pressed probability history. In this practical application, the analyzing module 14 generates a set of pressed probabilities related to the keys 11 according to the former keystroke sequence and comparing to the plurality set of default data and the pressed probability history. Subsequently, the selecting module 15 selects a target key from the plurality of keys 11 based on the set of pressed probability and the voltage variation information.

In practical application, the voltage variation information comprises at least a voltage variation, and each of the voltage variations is corresponding to one of the plurality of keys 11. The set of pressed probability comprises at least a pressed probability, and each of the pressed probabilities is corresponding to one of the plurality of keys 11. The selecting module 15 could perform a judgment function to select the target key, and the judgment function is a functional relationship between the target key and each of the set of pressed probability and the voltage variation information related to the keys 11. The database 13 could be a telephone directory provided by the telecommunication service or a users' address book. The former keystroke sequence comprises at least a number, and each of the numbers is corresponding to one of the plurality of keys 11.

Additionally, input device 10 could further comprise a display module (not shown in the figure). The display module is connected to the recording module 12 and the selecting module 15, for revealing the former keystroke sequence and a symbol corresponding to the target key, such as revealing a former dialed number or a selected number related to a target key on the screen of the mobile phone.

For example, if a user wants to dial a set of numbers “0910524875” using a mobile phone with the input device 10 of the present invention and he has dialed the former seven numbers “0910524”, however, he carelessly presses “8”, “7” and “5” three keys at the same time while dialing the eighth number. Assuming that the measured voltage variation of “8”, “7” and “5” three keys are 0.21V, 0.19V and 0.23V respectively, then “5” is regarded as user's destination of pressed keys according to the prior art, and on the mobile phone screen is shown the dialed partial numbers “09105245”. However, the result is not the same as expected. The main reason of the error result is that the voltage variation of each key is very similar, so judging the key which has a maximum voltage variation as the users' destination of pressed key is not a precise way and easily results in an erroneous judgment.

Furthermore, if a user wants to input an e-mail address “abcd@efg.hij” using a mobile phone with the input device 10 of the present invention and he has inputted the former seven letters “abcd@ef”, however, he carelessly presses “f”, “g” and “t” three keys at the same time while inputting the eighth letter. According to the prior art, on the mobile phone screen is shown the inputted partial letters “abcd@effgt”. However, the result is not the same as expected. The main reason of the error result is that the voltage variation of each key is very similar, so judging the key which has a maximum voltage variation as the users' destination of pressed key is not a precise way and easily results in an erroneous judgment.

So take the example of dialing a set of numbers using the mobile phone as mentioned above, according to the technique of the present invention, the mobile phone records not only the measured voltage variation of “8”, “7” and “5” three keys, but also analyzes and compares the dialed partial numbers “0910524” with the telephone directory or address book provided by the telecommunication service or users'. If in the telephone directory or address book, there are 20 sets of numbers which start with “0910524” and the following number is “8”, “7” or “5”, wherein there are 12 sets with the following number is “8”, 3 sets with the following number is “7” and 5 sets with the following number is “5”. Namely, the probabilities of “8”, “7” and “5” three keys being pressed are 60%, 15%, and 25%, respectively. Accordingly, the judgment function is finally substituted by each of the voltage variation and the pressed probability related to the keys, for example, the judgment. function could be the maximum of the voltage variation times the pressed probability related to each key, so that “8” would be regarded as users' destination of the pressed key.

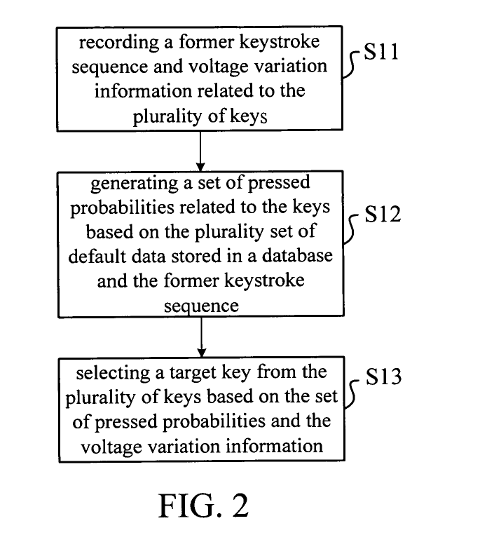

The second embodiment of the present invention is a method of operating an input device. Please refer to FIG. 2, FIG. 2 is a flow chart demonstrating the method of operating the input device according to the second embodiment. Firstly, step S11 is performed to record a former keystroke sequence and voltage variation information related to the plurality of keys. Secondly, step S12 is performed to generate a set of pressed probabilities related to the keys based on a plurality set of default data stored in a database and the former keystroke sequence. Finally, step S13 is performed to select a target key from the plurality of keys based on the set of pressed probabilities and the voltage variation information.

In practical application, the voltage variation information comprises at least a voltage variation, and each of the voltage variations is corresponding to one of the plurality of keys. The former keystroke sequence comprises at least a number, and each of the numbers is corresponding to one of the plurality of keys. The database is a telephone directory or an address book. The set of pressed probabilities comprises at least a pressed probability, and each of the pressed probabilities is corresponding to one of the plurality of keys. Namely, when not only one key is pressed, the set of pressed probability and the voltage variation information related to the keys are substituted to a function for selecting the target key in step S13 in the present invention.

Additionally, the method could reveal the former keystroke sequence and a symbol corresponding to the target key

Compared to the prior art, the input device the operating method thereof of the invention can reduce the probability of erroneous judgment while the plurality of capacitance keys are pressed simultaneously so that the voltage variation of each key is very similar. Owing to the accuracy of judging the pressed key is increased effectively, it is more convenient for users while operating the input devices.

Although the present invention has been illustrated and described with reference to the preferred embodiment thereof, it should be understood that it is in no way limited to the details of such embodiment but is capable of numerous modifications within the scope of the appended claims.

What is claimed is:

1. An input device comprising:
a plurality of keys;
a recording module connected to the keys, for recording a former keystroke sequence and voltage variation information related to the keys;
a database for storing a plurality set of default data;
an analyzing module connected to the recording module and the database, for generating a set of pressed probabilities related to the keys based on the plurality set of default data and the former keystroke sequence; and
a selecting module connected to the recording module and the analyzing module, for selecting a target key from the plurality of keys based on the set of pressed probabilities and the voltage variation information.

2. The input device of claim 1, wherein the voltage variation information comprises at least a voltage variation, and each of the voltage variations is corresponding to one of the plurality of keys.

3. The input device of claim 2, wherein the set of pressed probability comprises at least a pressed probability, and each of the pressed probabilities is corresponding to one of the plurality of keys.

4. The input device of claim 3, wherein the selecting module performs a judgment function to select the target key, and the judgment function is a functional relationship between the target key and each of the set of pressed probability and the voltage variation information related to the keys.

5. The input device of claim 1, wherein the database is a telephone directory or an address book.

6. The input device of claim 1, wherein the former keystroke sequence comprises at least a number, and each of the numbers is corresponding to one of the plurality of keys.

7. The input device of claim 1 further comprising:
a display module connected to the recording module and the selecting module, for revealing the former keystroke sequence and a symbol corresponding to the target key.

8. A method of operating an input device, the method comprising the following steps:
(a) recording a former keystroke sequence and voltage variation information related to the plurality of keys;
(b) generating a set of pressed probability related to the keys based on a plurality set of default data stored in a database and the former keystroke sequence; and
(c) selecting a target key from the plurality of keys based on the set of pressed probabilities and the voltage variation information.

9. The method of claim 8, wherein the voltage variation information comprises at least a voltage variation, and each of the voltage variations is corresponding to one of the plurality of keys.

10. The method of claim 9, wherein the set of pressed probability comprises at least a pressed probability, and each of the pressed probabilities is corresponding to one of the plurality of keys.

11. The method of claim 10, wherein each of the set of pressed probabilities and the voltage variation information related to the keys are substituted to a function for selecting the target key in step (c).

12. The method of claim 8, wherein the database is a telephone directory or an address book.

13. The method of claim 8, wherein the former keystroke sequence comprises at least a number, and each of the numbers is corresponding to one of the plurality of keys.

14. The method of claim 8 further comprising the following step:
revealing the former keystroke sequence and a symbol corresponding to the target key.
